(19) United States
(12) Patent Application Publication
(10) Pub. No.: US 2013/0006554 A1
(43) Pub. Date: Jan. 3, 2013

(54) ELECTRONIC DEVICE WITH ELECTRICITY RECORDING FUNCTION AND ELECTRICITY RECORDING METHOD THEREOF

(75) Inventors: Chien-Hung Chen, Changhua County (TW); Kuo-Chang Chen, Hsinchu County (TW)

(73) Assignee: ALTEK CORPORATION, HSINCHU (TW)

(21) Appl. No.: 13/192,725

(22) Filed: Jul. 28, 2011

(30) Foreign Application Priority Data
Jul. 1, 2011 (TW) 100123331

(51) Int. Cl. G06F 19/00; G01R 21/00

(52) U.S. Cl. 702/60

(57) ABSTRACT

This invention discloses an electronic device with electricity recording function and an electricity recording method thereof. The electronic device comprises a power module, a gauging module, a storage module and a processing module. A type and a level of the power module are gauged by the gauging module and stored by the storage module during a buffering time before the electronic device is shut down. When the electronic device is powered on, the processing module is used to take the type and the level of the power module from the storage module for reducing the waiting time of the electronic device when it is powered on.

### CROSS-REFERENCE TO RELATED APPLICATION

This application claims the benefit under 35 U.S.C. §119 of Taiwanese Patent Application No. 100123331, filed Jul. 1, 2011, which is hereby incorporated by reference in its entirety.

### BACKGROUND OF THE INVENTION

1. Field of the Invention

The present invention relates to an electronic device with an electricity recording function and an electricity recording method thereof, in particular to an electronic device with an electricity recording function and an electricity recording method thereof. The battery level of the electronic device is measured and stored, while the electronic device enters into a power-off procedure, such that the battery gauging procedure can be skipped during the next power-on process of the electronic device.

2. Description of the Related Art

At present, most people use digital image capturing device, such as a digital camera or a smart phone, to take pictures to keep great photos or videos for memory. There are two important information of battery power remaining information required during the power-on procedure of the camera.

One is battery Type, such as the type of AA battery or lithium battery. According to the battery type, the electric power discharge property of the battery can be determined for more accurate estimation of the remaining electric power.

The other is battery level which is the current operating voltage that the battery can supply. Camera has to assure that the remaining power is sufficient to push a camera lens out or retract the camera lens, so as to prevent the lens from exposing to the outside after the camera is shut down.

In traditional camera, a battery gauging procedure must be carried out during the power-on procedure to obtain the aforementioned two battery information. In the battery gauging procedure, the battery is provided a full load to detect the operating voltage supplied by the battery thereafter and the detected operating voltage can be used to determine the remaining electric power. However, the full load testing consumes some time, and the camera can continue other steps of power-on procedure, such as pushing the lens and entering into a live view, etc., only after the battery gauging procedure is completed.

From the description above, the execution of the battery gauging procedure provide a heavier load to the battery and must hold a certain period of time (approximately equal to 70˜100 ms) for accurate measurement of the operating voltage. Therefore, after a user presses the power-on button, the battery gauging procedure is then activated and its running time will affect the following two time points, one is timing of showing a live view on a screen, and the other is the timing of starting to take a picture.

In addition, frequent executions of the full load test will damage the battery and result in a shorter battery life. Besides, the status of AA battery is relatively unstable, the power level may be measured as a sufficient level even when the battery is exhausted, and it may cause a misjudgment. To solve such problem, a higher acceptable operating voltage is generally set for the battery gauging procedure of the first power-on, but such manner may result in a wrong determination of insufficient electric power when the battery power is sufficient.

### BRIEF SUMMARY

In view of the shortcomings of the prior art, it is a primary objective of the present invention to provide an electronic device with an electricity recording function and an electricity recording method thereof to overcome the problems of resulting in a long power-on time due to the checking of the battery level during the power-on of a camera, a long waiting time for taking a picture, a possible damage to the battery by the full load test and a wrong estimation of the battery level.

To achieve the foregoing objective, the present invention provides an electronic device with an electricity recording function, comprising a power module, a gauging module, a storage module and a processing module. The gauging module is electrically coupled to the power module, and the gauging module measures a type and a power level of the power module during a buffering time before the electronic device is shut down. The storage module is electrically coupled to the gauging module and provided for storing the type and the power level measured by the gauging module. The processing module is electrically coupled to the gauging module, and the type and the power level stored in the storage module are retrieved from the storage module when the electronic device is powered on.

Wherein, the electronic device of the present invention further comprises a detection module electrically coupled to the power module and provided for determining whether or not the power module has been removed after the electronic device is shut down.

Wherein, the electronic device of the present invention further comprises a clock module electrically coupled to the detection module, wherein the clock module comprises a buffer unit for recording information of the electronic device being shut down, and the content of the information stored in the buffer unit is changed if the detection module detects that the power module has been removed.

Wherein, the processing module is coupled to the clock module, and the process module access information stored in the buffer unit when the electronic device is powered on, so as to determine whether or not the power module has been removed after the electronic device is shut down.

Wherein, if the processing module determines that the power module has not been removed after the electronic device is shut down, the processing module retrieves the type and the power level of the power module from the storage module, and if the processing module determines that the power module has ever been removed after the electronic device is shut down, then the processing module drives the gauging module to gauge the power module.

Wherein, the electronic device is an image capturing device, and the image capturing device retrieves the type and the power level of the power module from the storage module and then enters into a live view, when the electronic device is powered on.

To achieve the objective of the present invention, the invention further provides an electronic device with an electricity recording function, comprising: a storage module, a detection module, a clock module and a processing module. The storage module is provided for storing a type and a power level of a power module during a buffering time before the electronic device is shut down. The detection module is provided for detecting whether or not the power module has been removed after the electronic device is shut down. The clock module is electrically coupled to the detection module and provided for changing the content stored in a buffer unit of the clock module if the detection module detects that the power module has been removed. The processing module is electrically coupled to the storage module and the clock module, and provided for reading the content from the buffer unit when the electronic device is powered on , so as to determine whether the power module has been removed after the electronic device is shut down, wherein, if the processing module determines that the power module has not been removed, then the processing module retrieves the type and the power level of the power module stored in the storage module.

To achieve the objective of the present invention, the invention further provides an electricity recording method applied in an electronic device and comprising the steps of: measuring a type and a power level of a power module by a gauging module during a buffering time before the electronic device is shut down; using a storage module to store the type and the power level measured by the gauging module; and using a processing module to retrieve the type and the power level of the power module from the storage module when the electronic device is powered on.

Both electronic device with an electricity recording function and electricity recording method of the present invention have one or more of the following advantages:

(1) The electronic device measures the battery before the camera is powered off, and the measured battery type and current remaining power level are stored, such that there is no need for measuring the battery when the camera is powered on for its use, so as to simplify the camera power-on procedure and shorten the time from the camera being powered on to the camera entering a live view.

(2) The electronic device needs not to perform a full load test of the load test to obtain information of the measured battery, so as to reduce the damage of the battery.

(3) The battery level is measured and stored before the electronic device is shut down, and the battery can be determined whether or not it has ever been removed in order to provide a more accurate estimation of the battery level.

The technical characteristics and effects of the present invention will become apparent in the detailed description of the preferred embodiments with reference to the accompanying drawings as follows.

### BRIEF DESCRIPTION OF THE DRAWINGS

FIG. 1 is a schematic view of an electronic device with an electricity recording function in accordance with a first preferred embodiment of the present invention;

FIG. 2 is a flow chart of an electricity recording method in accordance with the first preferred embodiment of the present invention;

FIG. 3 is a schematic view of an electronic device with an electricity recording function in accordance with a second preferred embodiment of the present invention;

FIG. 4 is a flow chart of an electricity recording method in accordance with the second preferred embodiment of the present invention;

FIG. 5 is a schematic view of an electronic device with an electricity recording function in accordance with a third preferred embodiment of the present invention; and

FIG. 6 is a flow chart of an electricity recording method in accordance with the third preferred embodiment of the present invention.

### DETAILED DESCRIPTION

The technical characteristics and contents of the present invention will become apparent with the following detailed description and related drawings. It is noteworthy to point out that same numerals are used for representing respective same elements in the drawings.

The electronic device with an electricity recording function of the present invention can be various electronic devices with a photographic function such as digital cameras, camera phone, smart phones and digital video cameras. However, the electricity recording method of the present invention is not limited to the application of image capturing devices or cameras only, but can also be used in any other electronic device having a battery. The following embodiments adopt the measurement of a battery level of an image capturing device is used for illustrating the present invention, but it is noteworthy to point out again that the application of the invention is not limited to the image capturing devices.

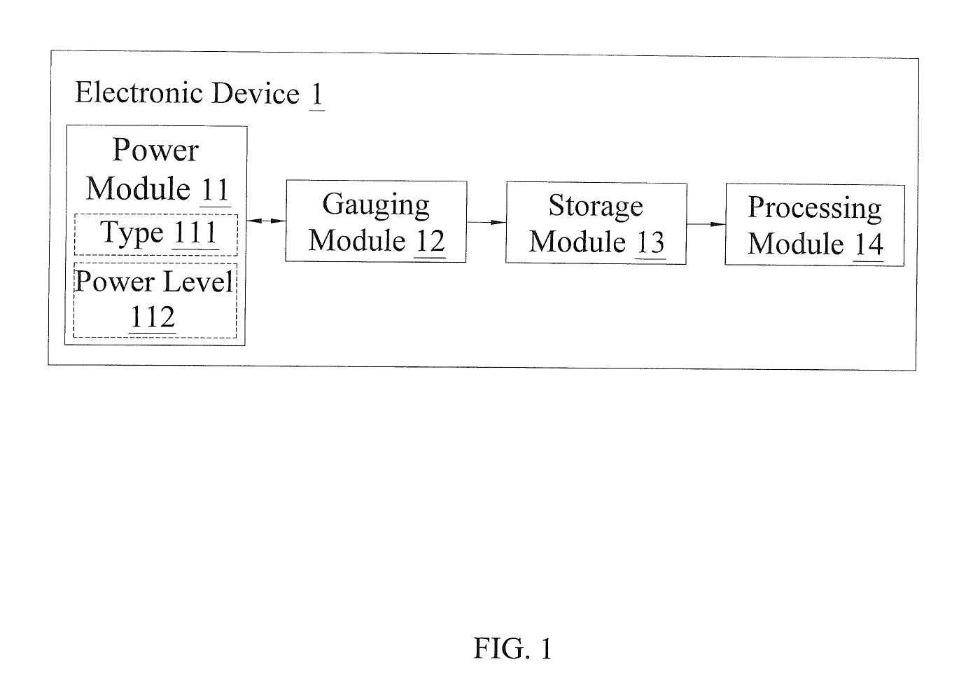

With reference to FIG. 1 for an electronic device with an electricity recording function in accordance with the first preferred embodiment of the present invention, the electronic device 1 can be a camera and comprises a power module 11, a gauging module 12, a storage module 13 and a processing module 14. The power module 11 is electrically coupled to the gauging module 12, and the gauging module 12 is electrically coupled to the storage module 13, and the storage module 13 is electrically coupled to the processing module 14. The power module 11 is a general battery such as a lithium battery or a zinc-manganese battery or a rechargeable battery such as a lithium-ion battery, lead-acid battery, a nickel-cadmium battery, and each battery can be subdivided into different models of batteries. For example, a dry cell can be divided into AA battery and AAA battery. The storage module 13 can be a built-in memory, but the invention is not limited to such arrangement only.

In the first preferred embodiment, if it is necessary to shut down the electronic device 1, the gauging module 12 will execute a battery gauging procedure on the power module 11 during a buffering time before the electronic device 1 is shut down, in order to measure a type 111 and the current remaining power level 112 of the power module 11. After the type 111 and the current power level 112 of the power module 11 are measured, the storage module 13 will store the detected information (including the type 111 and the power level 112), such that when a user wants to use the electronic device 1 to take pictures, the user can power on the electronic device 1, and the processing module 14 will retrieve the type 111 and the current remaining power level 112 from the storage module 13, and then the electronic device 1 will enter into a live view and get ready for the user to start taking the pictures.

As described above, the power module 11 is measured primarily when the electronic device 1 is shut down. When the electronic device 1 is powered on, the procedure of measuring the type and the current power level of the power module 11 can be skipped, since the type and the current power level of the power module 11 can be retrieved directly from the storage module 13, so as to reduce the time from the electronic device 1 being powered on to the electronic device 1 entering into a live view. It is noteworthy to point out that when the electronic device 1 is shut down, a battery gauging of the power module 11 is performed, instead of applying a full load to the power module 11 for the full load test, so that the damage of the power module 11 can be minimized effectively.

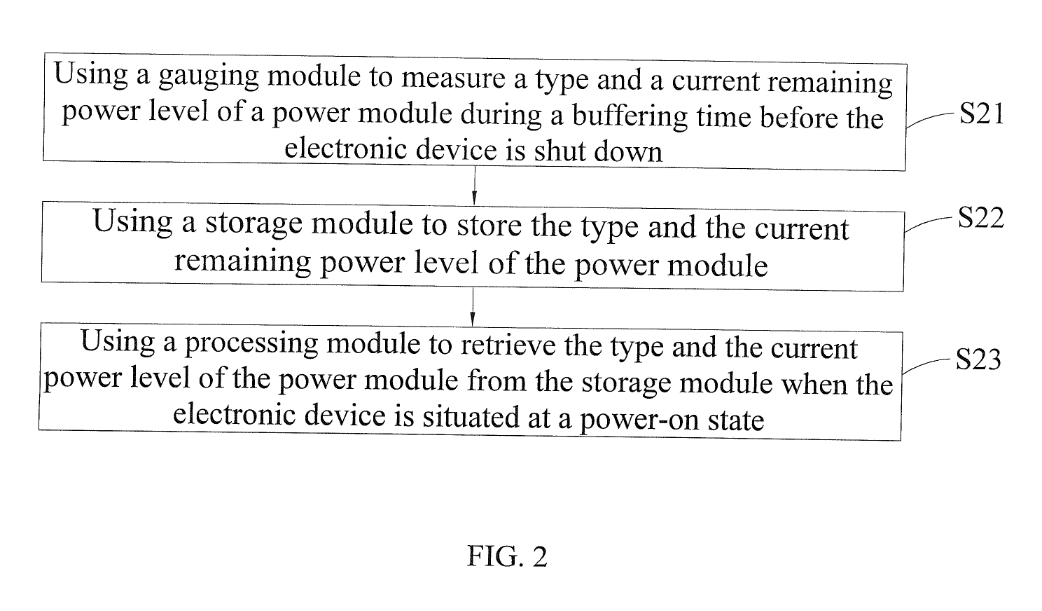

With reference to FIG. 2 for a flow chart of an electricity recording method in accordance with the first preferred embodiment of the present invention, the procedure of gauging the battery of an electronic device 1 comprises the following steps:

S21: Use the gauging module 12 to measure the type 111 and the current remaining power level 112 of the power module 11 during a buffering time before the electronic device 1 is shut down.

S22: Use the storage module 13 to store the measured type 111 and current remaining power level 112 of the power module 11.

S23: Use the processing module 14 to retrieve the type 111 and the current power level 112 of the power module 11 from the storage module 13 when the electronic device 1 is situated at a power-on state.

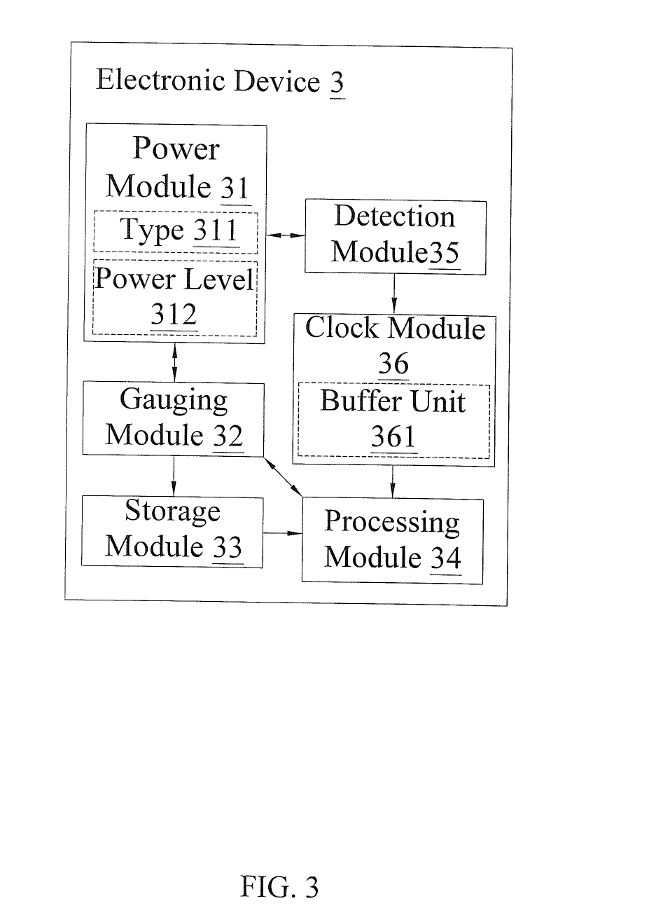

With reference to FIG. 3 for an electronic device with an electricity recording function in accordance with the second preferred embodiment of the present invention, the electronic device 3 can be a camera, but the invention is not limited to cameras only. The electronic device 3 comprises a power module 31, a gauging module 32, a storage module 33, a processing module 34, a detection module 35 and a clock module 36. The power module 31 is electrically coupled to the gauging module 32 and the detection module 35, and the gauging module 32 is electrically coupled to the storage module 33 and the processing module 34, and the processing module 34 is electrically coupled to the storage module 33 and the clock module 36, and the clock module 36 is electrically coupled to the detection module 35. The power module 31 can be a general battery or a chargeable battery. The storage module 33 can be a built-in memory. The clock module 36 includes a buffer unit 361, and the clock module 36 is a real-time clock (RTC). When the electronic device 3 is shut down, the clock module 36 is provided for recording information of the electronic device 3 being shut down into the buffer unit, wherein the information includes the shutdown time of the electronic device 3.

In the second preferred embodiment, when the electronic device 3 is shut down, the gauging module 32 performs a battery gauging on the power module 31 during a buffering time before the electronic device 3 is shut down, in order to measure the type 311 and the current remaining power level 312 of the power module 31, and then the measured type 311 and the current power level 312 of power module 31 are stored in the storage module 33. The detection module 35 will determine whether or not the power module 31 has been removed after the electronic device 3 is shut down. If the detection module 35 determines that the power module 31 has ever been removed, the content stored in the buffer unit 361 of the clock module 36 will be updated.

As described above, when the electronic device 3 is powered on, the processing module 34 reads the content stored in the buffer unit 361 of the clock module 36 to determine whether or not the power module 31 has ever been removed. If the power module 31 has ever been removed, the processing module 34 will drive the gauging module 32 to measure the power level 312 and the type 311 of the power module 31. If the power module 31 has not ever been removed, then the processing module 34 will retrieve the previously measured type 311 and current power level 312 of the power module 31 directly from the storage module 33 when the electronic device 3 is shut down. When the electronic device 3 is shut down, the gauging module 32 measures the type 311 and the current power level 312 of the power module 31, so that the power-on procedure of the electronic device 3 needs not measure the power module 31, but retrieve the information directly from the storage module 33 to reduce the time from the electronic device 3 being powered on to the electronic device 3 being ready to take pictures. Since the measurement of the electric power level of the power module 31 takes place when the electronic device 3 is shut down, and the detection module 35 is used for determining whether or not the power module 31 has ever been removed, the electronic device 3 according to the present invention can obtain a more accurate power level 312 of the power module 31 comparing with the method that the measurement of the electric power level of the power module 31 takes place when the electronic device 3 is powered on.

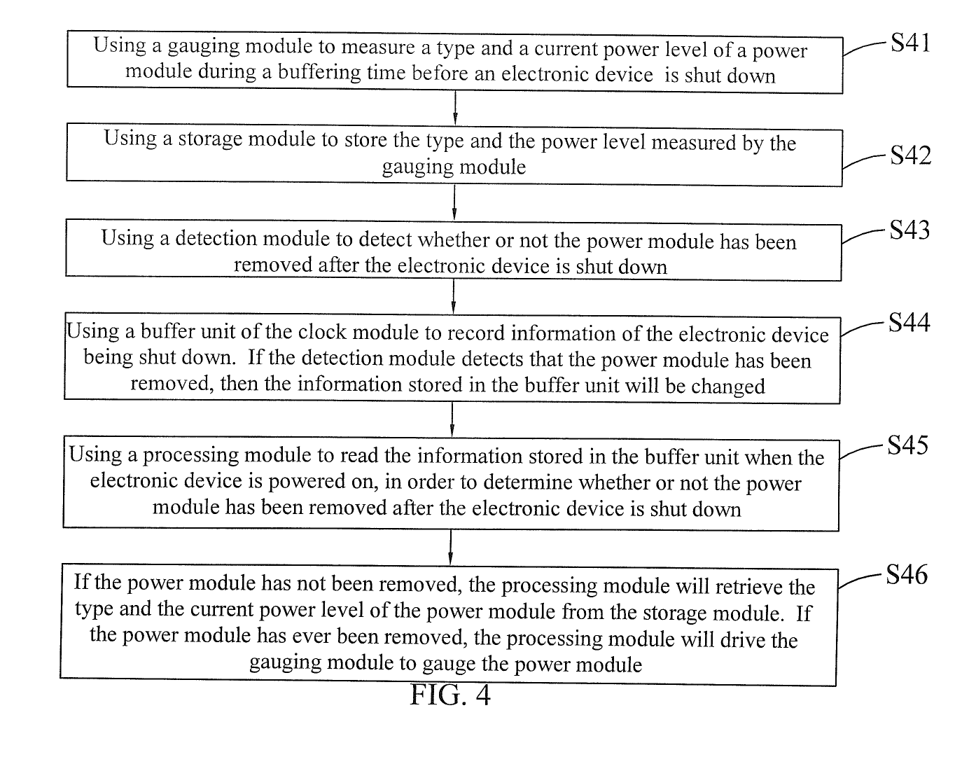

With reference to FIG. 4 for a flow chart of an electricity recording method in accordance with the second preferred embodiment of the present invention, the procedure of gauging the battery of an electronic device 3 comprises the following steps:

S41: Using the gauging module 32 to measure the type 311 and the current power level 312 of the power module 31 of the electronic device 3 during a buffering time before the electronic device 3 is shut down.

S42: Using the storage module 33 to store the type 311 and the power level 312 measured by the gauging module 32.

S43: Using the detection module 35 to detect whether or not the power module 31 has been removed after the electronic device 3 is shut down.

S44: Using a buffer unit 361 of the clock module 36 to record information of the electronic device 3 being shut down. If the detection module 35 detects that the power module 31 has been removed, then the information stored in the buffer unit 361 will be changed.

S45: Using the processing module 34 to read the information stored in the buffer unit 361 when the electronic device 3 is powered on, in order to determine whether or not the power module 31 has been removed after the electronic device 3 is shut down.

S46: If the power module 31 has not been removed, the processing module 34 will retrieve the type 311 and the current power level 312 of the power module 31 from the storage module 33. If the power module 31 has ever been removed, the processing module 34 will drive the gauging module 32 to gauge the power module 31.

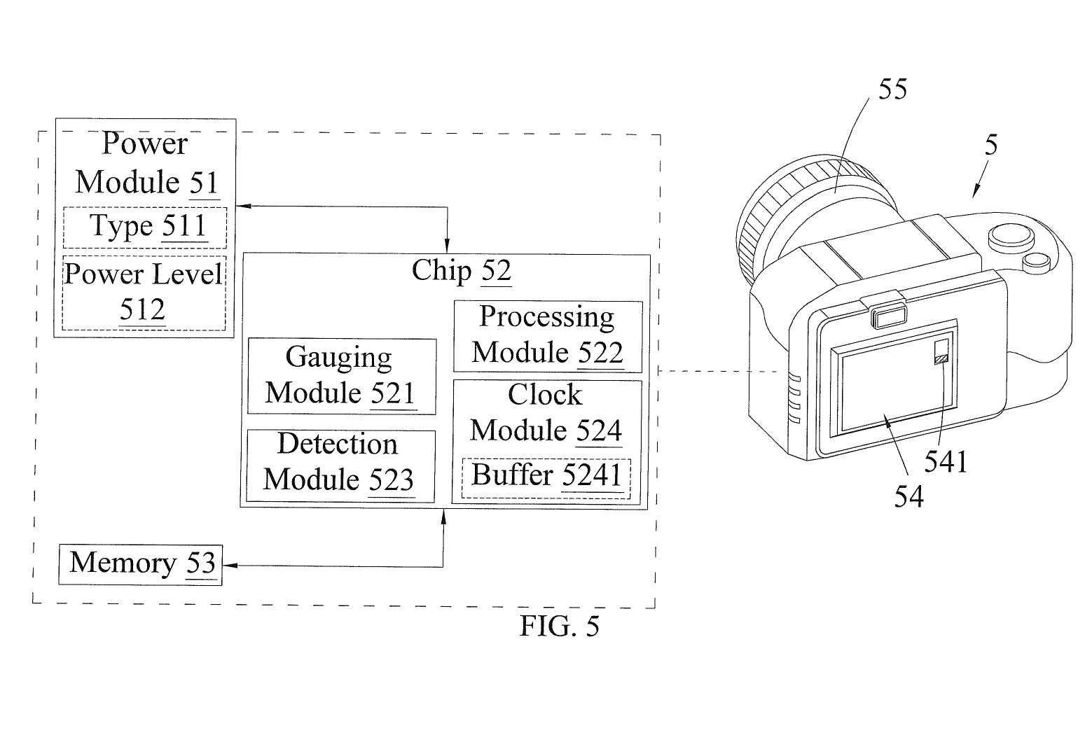

With reference to FIG. 5 for an electronic device with an electricity recording function in accordance with the third preferred embodiment of the present invention, the electronic device 3 is an image capturing device 5 comprising a battery 51, a chip 52 and a memory 53. The chip 52, the battery 51 and the memory 53 are electrically coupled. The chip 52 includes a gauging module 521, a processing module 522, a detection module 523 and a clock module 524. The clock module 524 includes a buffer 5241. The image capturing device 5 includes a screen 54 and a lens 55 installed externally.

In the third preferred embodiment, when the user finishes using the image capturing device 5 and wants to shut down the image capturing device 5, the gauging module 521 of the chip 52 will start measuring the battery 51 during a buffering time from the user pressing a shutdown button to the image capturing device 5 being completely shut down, and obtaining a type 511 and a current power level 512 of the battery 51, and storing the type 511 and the current power level 512 into the memory 53. The detection module 523 of the chip 52 is provided for detecting whether or not the battery 51 has ever been removed when the image capturing device 5 is shut down or after the image capturing device is shut down. If yes, then the content stored in the buffer 5241 of the clock module 524 of the chip 52 will be changed.

As described above, if the user wants to use the image capturing device 5 and powers on the image capturing device 5, the processing module 522 of the chip 52 will read the content from the buffer 5241 to determine whether or not the battery 51 has ever been removed. If the battery 51 has not ever been removed, the processing module 522 will retrieve the previously stored type 511 and current power level 512 of the battery 51 directly from the memory 53 when the image capturing device 5 is previously shut down. If the processing module 522 determines that the battery 51 has ever been removed, then the processing module 522 will drive the gauging module 521 to gauge the electric power level of the battery 51. After the information including the type 511 and the current power level 512 of the battery 51 are obtained, the screen 54 of the image capturing device 5 will enter into a live view, and a power indicating icon 541 of the current power level 512 of the battery 51 is displayed on the screen 54, while the lens 55 of the image capturing device 5 will be pushed out to allow the user to take picture by using the image capturing device 5.

As described above, if the battery 51 has not been removed, the processing module 522 retrieves related information including the current power level 512 of the battery 51 directly from the memory 53, such that when the user presses a power-on button of the image capturing device 5, the waiting time of pushing out the lens 55 and the screen 54 entering into a live view can be shortened. It is noteworthy to point out that the gauging module 521 of the chip 52 can measure the power level 512 of the battery 51 at regular time intervals after the image capturing device 5 is powered on to confirm the consumption of the current electric power of the battery 51.

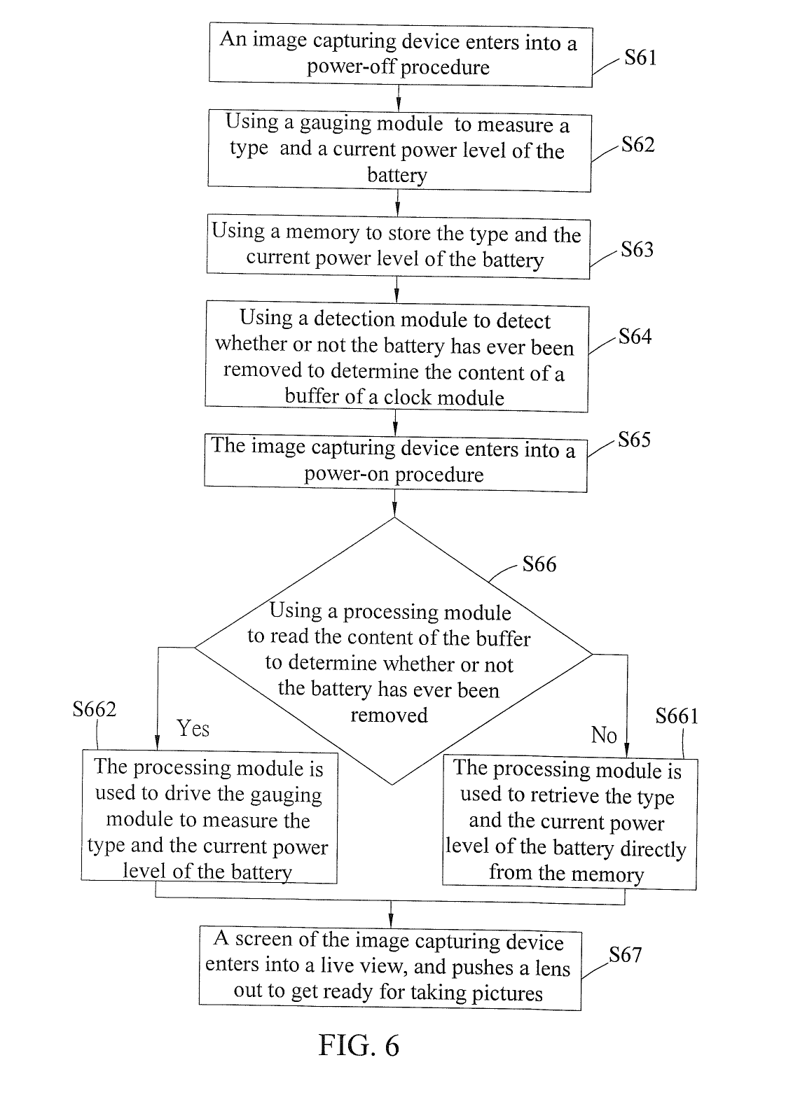

With reference to FIG. 6 for a flow chart of an electricity recording method in accordance with the third preferred embodiment of the present invention, the procedure of gauging the battery of an electronic device 5 comprises the following steps:

S61: The image capturing device 5 enters into a power-off procedure.

S62: Using the gauging module 521 to measure the type 511 and the current power level 512 of the battery 51.

S63: Using the memory 53 to store the type 511 and the current power level 512 of the battery 51.

S64: Using the detection module 523 to detect whether or not the battery 51 has ever been removed to determine the content of the buffer 5241 of the clock module 524.

S65: The image capturing device 5 enters into a power-on procedure.

S66: Using the processing module 522 to read the content of the buffer 5241 to determine whether or not the battery 51 has ever been removed.

S661: If the battery 51 has not ever been removed, then the processing module 522 is used to retrieve the type 511 and the current power level 512 of the battery 51 directly from the memory 53.

S662: If the battery 51 has ever been removed, then the processing module 522 is used to drive the gauging module 521 to measure the type 511 and the current power level 512 of the battery 51.

S67: The screen 54 of the image capturing device 5 enters into a live view, and the image capturing device 5 pushes the lens 55 out to get ready for taking pictures.

In summation of the description above, the electronic device with an electricity recording function and the electricity recording function in accordance with the present invention can measure and store the electric power level of the battery before the electronic device is shut down and detect whether or not the battery has ever been removed, so that when the electronic device is powered on, the information ,the power level of the battery, etc., can be retrieved directly from the memory to skip the measurement of the battery during the power-on procedure of the electronic device, and reduce the power-on time, so as to shorten the user's waiting time of taking a picture. Compare with the battery gauging procedure taken before the electronic device is powered on, the battery level measured by the electronic device of the present invention is more accurate. In addition, the electric power level is measured without using the full load test conducted during the power-on procedure and before the electronic device is shut down, so that the loss or damages of the batter can be minimized effectives to improve the battery life.

What is claimed is:

1. An electronic device with an electricity recording function, comprising:
a power module;
a gauging module electrically coupled to the power module, measuring a type and a power level of the power module during a buffering time before the electronic device being shut down;
a storage module electrically coupled to the gauging module, storing the type and the power level measured by the gauging module; and
a processing module electrically coupled to the gauging module and the storage module retrieving the type and the power level of the power module from the storage module when the electronic device being powered on.

2. The electronic device with an electricity recording function as recited in claim 1, further comprising a detection module electrically coupled to the power module, detecting that whether or not the power module has been removed after the electronic device being shut down.

3. The electronic device with an electricity recording function as recited in claim 2, further comprising
a clock module electrically coupled to the detection module; wherein the clock module comprises a buffer unit for recording information of the electronic device being shut down, and the content of the information stored in the buffer unit is changed if the detection module detecting that the power module has been removed.

4. The electronic device with an electricity recording function as recited in claim 3, wherein the processing module is coupled to the clock module, and processing module access the information stored in the buffer unit when the electronic device is powered on, so as to determine whether or not the power module has been removed after the electronic device is shut down.

5. The electronic device with an electricity recording function as recited in claim 4, wherein the processing module retrieves the type and the power level of the power module from the storage module if the processing module determines that the power module has not been removed after the electronic device is shut down, and drives the gauging module to gauge the power module if the processing module determines that the power module has ever been removed after the electronic device is shut down.

6. The electronic device with an electricity recording function as recited in claim 1, wherein the electronic device is an image capturing device, and the image capturing device retrieves the type and the power level of the power module from the storage module and then enters into a live view, when the electronic device is powered on.

7. An electronic device with an electricity recording function, comprising:
a storage module storing a type and a power level of a power module during a buffering time before the electronic device being shut down;
a detection module detecting that whether or not the power module has been removed after the electronic device being shut down;
a clock module electrically coupled to the detection module, changing the content stored in a buffer unit of the clock module if the detection module detecting that the power module has been removed;
a processing module electrically coupled to the storage module and the clock module, determining that whether the power module has been removed after the electronic device being shut down according to the content stored in the buffer unit when the electronic device being powered on, wherein if the processing module determines that the power module has not been removed , the processing module retrieves the type and the power level of the power module stored in the storage module.

8. The electronic device with an electricity recording function as recited in claim 7, further comprising a gauging module measuring the type and the power level of the power module.

9. The electronic device with an electricity recording function as recited in claim 8, wherein the processing module drives the gauging module to gauge the power module when the electronic device is powered on if the processing module determines the power module has been removed after the electronic device is shut down.

10. The electronic device with an electricity recording function as recited in claim 7, wherein the electronic device is an image capturing device, and the image capturing device retrieves the type and the power level of the power module from the storage module and then enters into a live view, when the electronic device is powered on.

11. An electricity recording method, applied in an electronic device, comprising the steps of:
measuring a type and a power level of a power module by a gauging module during a buffering time before the electronic device being shut down;
using a storage module to store the type and the power level measured by the gauging module; and
using a processing module to retrieve the type and the power level of the power module from the storage module when the electronic device being powered on.

12. An electricity recording method as recited in claim 11, further comprising the step of using a detection module to detect that whether or not the power module has been removed, after the electronic device being shut down.

13. An electricity recording method as recited in claim 12, further comprising the steps of using a buffer unit of a clock module to record information of the electronic device being shut down, and changing the content of the information stored in the buffer unit if the detection module detecting that the power module has been removed.

14. An electricity recording method as recited in claim 13, further comprising the step of: using the processing module to read the content of information stored in the buffer unit when the electronic device being powered on, so as to determine that whether the power module has been removed after the power module being shut down; wherein if the processing module determines that the power module has not been removed, the processing module retrieves the type and the power level of the power module from the storage module; wherein if the processing module determines that the power module has been removed, the processing module drives the gauging module to gauge the power module.

15. An electricity recording method as recited in claim 11, wherein the electronic device is an image capturing device, and the image capturing device enters into a live view after the image capturing device is powered on, and the type and the power level of the power module are retrieved from the storage module.
